(19) United States
(12) Patent Application Publication
(10) Pub. No.: US 2025/0202486 A1
(43) Pub. Date: Jun. 19, 2025

(54) KEY DEVICE AND ELECTRONIC APPARATUS HAVING SAME

(71) Applicant: Beijing Zitiao Network Technology Co., Ltd., Beijing (CN)

(72) Inventors: Lei ZHANG, Beijing (CN); Qiang LI, Beijing (CN)

(21) Appl. No.: 18/847,006

(22) PCT Filed: May 22, 2023
(86) PCT No.: PCT/CN2023/095461

§ 371 Date: Sep. 13, 2024

(30) Foreign Application Priority Data
Jun. 8, 2022 (CN) 202210646492.6

(51) Int. Cl. H03K 17/975; H03K 17/96

(52) U.S. Cl. CPC H03K 17/975; H03K 17/962; H03K 2217/96076

(57) ABSTRACT

A button unit and an electronic device are provided. The button unit includes a circuit board, a capacitive sensor being provided on the circuit board; a conductive bracket fixed on the circuit board and in electrical conduction with the capacitive sensor; a button assembly movable relative to the conductive bracket and including a conductive member and an insulating member, the conductive member including a first conductive portion, and the insulating member including a touch surface portion covering an outer side of the first conductive portion; and a conductive spring sandwiched between the conductive bracket and the button assembly and in electrical conduction with each of the conductive bracket and the conductive member.

### CROSS-REFERENCE TO RELATED APPLICATION

The present application is filed on the basis of Chinese Patent Application No. 202210646492.6, filed on Jun. 8, 2022, and claims the priority to the Chinese Patent Application, which is incorporated herein by reference in its entirety.

### TECHNICAL FIELD

The present application relates to the technical field of button units, and in particular to a button unit and an electronic device having same.

### BACKGROUND

In the related art, some capacitive sensing button units detect a touch through a change of charges caused by a user touching a cover plate which covers an outer end of a spring provided on a circuit board. However, the detection accuracy of the capacitive sensing button unit needs to be improved.

### SUMMARY

The present application is intended to solve at least one of the technical problems existing in the prior art. To this end, the present application provides a button unit, which can improve the accuracy of determination of touching.

The present application further provides an electronic device having the button unit mentioned above.

According to an embodiment of a first aspect of the present application, a button unit includes: a circuit board, a capacitive sensor being provided on the circuit board; a conductive bracket fixed on the circuit board and in electrical conduction with the capacitive sensor; a button assembly movable relative to the conductive bracket and including a conductive member and an insulating member, the conductive member including a first conductive portion, and the insulating member including a touch surface portion covering an outer side of the first conductive portion; and a conductive spring sandwiched between the conductive bracket and the button assembly and in electrical conduction with each of the conductive bracket and the conductive member.

In the button unit according to an embodiment of the present application, since the conductive member is further arranged between the conductive spring and the insulating member, compared with the solution in which the conductive spring is in direct contact with the insulating member, the yield of contact between the conductive member and the insulating member is higher, so that the stability of charge detection can be effectively improved, thereby increasing the reliability of determination and simplifying the design of the conductive spring. Moreover, since the conductive bracket is further arranged between the conductive spring and the circuit board, compared with the solution in which the conductive spring is in direct contact and electrical conduction with the circuit board, there is no need to specially design the conductive spring in order to meet the contact reliability and electrical conduction effectiveness, so that the design and machining of the conductive spring is simplified, and the reliability of indirect electrical conduction between the conductive spring and the circuit board is improved, thereby increasing the reliability of determination. In addition, by arranging the conductive bracket to support the conductive spring, it can be ensured that the conductive spring can effectively and stably exert the elasticity, thereby improving the touching feel and enhancing the user experience.

In some embodiments, the button assembly further includes: an insulating bracket connected to the insulating member and including a post portion, an axial end of the post portion being a support end, and the first conductive portion being sandwiched between the support end and the touch surface portion.

In some embodiments, the conductive spring is arranged around the post portion.

In some embodiments, the insulating bracket further includes: an outer cover portion, the post portion being arranged inside and connected to the outer cover portion, and the outer cover portion being connected to the insulating member, so as to define an accommodating cavity between the insulating bracket and the insulating member, and the conductive member being arranged inside the accommodating cavity.

In some embodiments, the outer cover portion covers the conductive spring.

In some embodiments, the insulating bracket further includes: a connecting portion connected between the post portion and the outer cover portion, the conductive spring and the conductive member being respectively located on two sides of the connecting portion in an axial direction of the post portion, avoidance holes being formed in the connecting portion, the conductive member further including a second conductive portion connected to a side of the first conductive portion facing the circuit board, and the second conductive portion passing through the avoidance holes and being in electrical conduction with the conductive spring.

In some embodiments, the connecting portion includes a plurality of sub-portions arranged at a distance from each other in a circumferential direction of the post portion, each avoidance hole is formed between every two adjacent sub-portions, and the second conductive portion passes through at least two of the avoidance holes.

In some embodiments, the shape of the avoidance holes matches with the shape of the second conductive portion, so that the circumferential rotation of the conductive member relative to the post portion is restricted by the connecting portion.

In some embodiments, taking a cross section of the post portion as a projection plane, an orthographic projection of the support end is within a range of an orthographic projection of the first conductive portion, and an orthographic projection of an axial end of the conductive spring facing the first conductive portion is within the range of the orthographic projection of the first conductive portion.

In some embodiments, a recess is formed in a side surface of the touch surface portion away from the first conductive portion, in the projection plane, the orthographic projection of the support end is within a range of an orthographic projection of the recess, and the orthographic projection of the recess is within the range of the orthographic projection of the first conductive portion.

In some embodiments, the post portion is a hollow post, and the other axial end of the post portion away from the support end is open.

In some embodiments, the conductive bracket includes a sleeve portion, and the conductive spring is arranged around the sleeve portion.

In some embodiments, the conductive bracket further includes a flared portion coaxially arranged with the sleeve portion and having a cross section that tapers in a direction away from the circuit board, the sleeve portion is connected to an end of the flared portion away from the circuit board, and an axial end of the conductive spring close to the circuit board abuts against an outer peripheral surface of the flared portion.

In some embodiments, the conductive bracket further includes an end plate portion and a foot portion, the end plate portion is connected to an outer periphery of an end of the flared portion close to the circuit board, and the foot portion extends from an edge of the end plate portion in a direction toward the circuit board and is supported on the circuit board, so as to allow the end plate portion to be in clearance-fit with the circuit board.

In some embodiments, the conductive spring includes a first spring section, a second spring section, and a third spring section that are connected in an axial direction of the conductive spring, the second spring section is located at a side of the first spring section close to the circuit board, the third spring section is connected between the first spring section and the second spring section, the second spring section has a larger diameter than the first spring section, the second spring section is arranged around the sleeve portion, the button assembly includes the post portion, and the first spring section is arranged around the post portion.

According to an embodiment of a second aspect of the present application, an electronic device includes: a device body and a button unit, the button unit being arranged on the device body and being a button unit according to an embodiment of the first aspect of the present application.

In the electronic device according to an embodiment of the present application, by arranging the button unit according to an embodiment of the first aspect, the user experience of the electronic device is enhanced.

In some embodiments, the device body includes a headpiece portion and a handle portion, and the button unit is arranged on the handle portion.

Additional aspects and advantages of the present application will be set forth in part in the following description, and in part will be apparent from the following description, or may be learned by practice of the present application.

### BRIEF DESCRIPTION OF DRAWINGS

FIG. 1 is an exploded view of a button unit according to an embodiment of the present application;

FIG. 2 is a front view of the button unit shown in FIG. 1;

FIG. 3 is a cross-sectional view taken along line A-A of FIG. 2;

FIG. 4 is an exploded view of a conductive member and an insulating bracket shown in FIG. 1; and

FIG. 5 is an exploded view of a circuit board, a conductive bracket and a conductive spring shown in FIG. 1.

### LIST OF REFERENCE SIGNS

Button unit 100;
Circuit board 1;
Conductive bracket 2; Sleeve portion 21; Flared portion 22; End plate portion 23; Foot portion 24;
Button assembly 3;
   Conductive member 31; First conductive portion 311; Second conductive portion 312;
   Insulating member 32; Touch surface portion 321; Connecting periphery 322; Recess 323;
   Insulating bracket 33; Post portion 331; Support end 332;
      Outer cover portion 333; First cover portion 3331; Second cover portion 3332;
      Connecting portion 334; Avoidance hole 3341; Sub-portion 3342;
Conductive spring 4; First spring section 41; Second spring section 42; Third spring section 43.

### DETAILED DESCRIPTION

Embodiments of the present application will be described in detail below. Examples of the embodiments are shown in the accompanying drawings, and throughout the drawings, the same or similar reference signs refer to the same or similar elements or elements having the same or similar functions. The embodiments described below with reference to the accompanying drawings are exemplary and are intended to be illustrative of the present application, but should not be construed as limiting the present application.

The following disclosure provides many different embodiments or examples to implement different structures of the present application. In order to simplify the disclosure of the present application, components and arrangements of specific examples are described below. Of course, they are only examples and are not intended to limit the present application. In addition, in the present application, reference numerals and/or reference letters may be repeated in different examples. This repetition is for the purpose of simplicity and clarity, and does not in itself indicate the relationship between the various embodiments and/or arrangements discussed. In addition, the present application provides examples of various specific processes and materials, but those of ordinary skill in the art can realize the applicability of other processes and/or the use of other materials.

A button unit 100 according to an embodiment of a first aspect of the present application is described below with reference to the accompanying drawings.

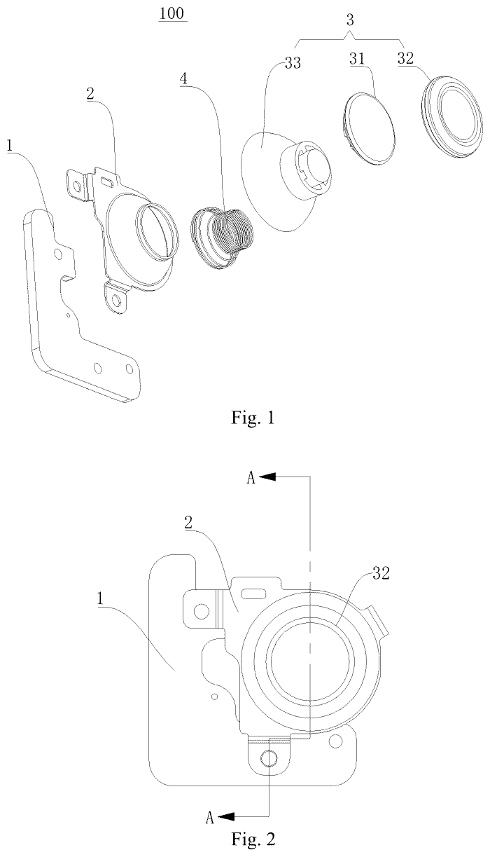

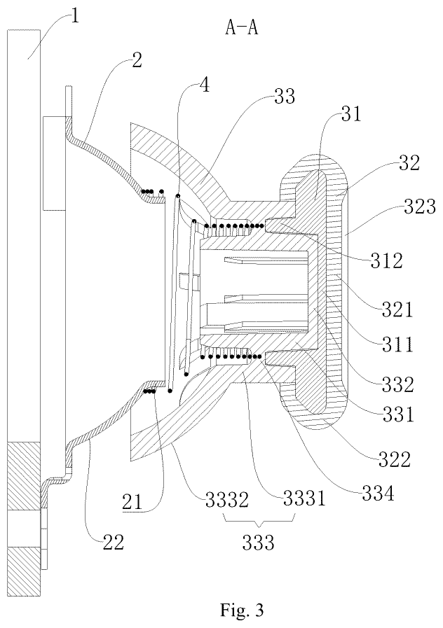

As shown in FIG. 1, the button unit 100 includes: a circuit board 1, a conductive bracket 2, a button assembly 3, and a conductive spring 4. A capacitive sensor is provided on the circuit board 1, and is configured to detect a change in capacitance to detect a touch. With reference to FIGS. 2 and 3, the conductive bracket 2 is fixed on the circuit board 1 and is in electrical conduction with the circuit board 1. The button assembly 3 is movable relative to the conductive bracket 2, and the button assembly 3 includes a conductive member 31 and an insulating member 32, the conductive member 31 including a first conductive portion 311, the insulating member 32 including a touch surface portion 321, the touch surface portion 321 being adapted to be touched and pressed, and the touch surface portion 321 covering an outer side of the first conductive portion 311. The conductive spring 4 is sandwiched between the conductive bracket 2 and the button assembly 3, and is in electrical conduction with each of the conductive bracket 2 and the conductive member 31.

In this way, by arranging the conductive member 31 on an inner side of the insulating member 32, and electrically conducting the conductive member 31 with the capacitive sensor on the circuit board 1 via the conductive spring 4 and the conductive bracket 2, a path for charges is realized, which makes it possible to sense a change of charges of the insulating member 32, and then, by means of software detection, whether a user touches the touch surface portion 321 is determined, thereby achieving the touch function of the button unit 100. It can be understood that the detailed working principles of the capacitive sensor are well-known to those skilled in the art and will not be described in detail here.

With the above structural design, the button unit 100 according to the embodiment of the present application can have at least the following beneficial effects. Firstly, since the conductive member 31 is further arranged between the conductive spring 4 and the insulating member 32, compared with the solution in which the conductive spring 4 is in direct contact with the insulating member 32, the yield of contact between the conductive member 31 and the insulating member 32 can be likely higher than the yield of contact between the conductive spring 4 and the insulating member 32, so that the stability of charge detection can be effectively improved, thereby increasing the reliability of determination and simplifying the design of the conductive spring 4. Secondly, since the conductive bracket 2 is further arranged between the conductive spring 4 and the circuit board 1, compared with the solution in which the conductive spring 4 is in direct contact and electrical conduction with the circuit board 1, there is no need to specially design the conductive spring 4 in order to meet the contact reliability and electrical conduction effectiveness, so that the design and machining of the conductive spring 4 is simplified, and the reliability of indirect electrical conduction between the conductive spring 4 and the circuit board 1 is improved, thereby increasing the reliability of determination. Thirdly, by arranging the conductive bracket 2 to support the conductive spring 4, it can be ensured that the conductive spring 4 can effectively exert the elasticity, thereby improving the touching feel and enhancing the user experience.

In some embodiments of the present application, as shown in FIG. 3, the button assembly 3 may further include an insulating bracket 33, the insulating bracket 33 being connected to the insulating member 32, and the insulating bracket 33 including a post portion 331. An axial end of the post portion 331 is a support end 332, and the first conductive portion 311 is sandwiched between the support end 332 and the touch surface portion 321. That is, the first conductive portion 311 is located on an axial side of the post portion 331, and the touch surface portion 321 is located on a side of the first conductive portion 311 away from the post portion 331.

In this way, when the user touches the touch surface portion 321, the post portion 331 can be used to support the first conductive portion 311 of the conductive member 31, so as to solve problems such as the deformation or separation of the first conductive portion 311 and the touch surface portion 321, so that the yield of contact between the first conductive portion 311 and the touch surface portion 321 is improved, and the stability of charge detection can be further effectively improved, thereby increasing the reliability of determination. In addition, with the supporting effect provided by the post portion 331, the touching feel can be improved, so as to avoid the feeling that the insulating member 32 collapses when touching.

Optionally, as shown in FIG. 3, the conductive spring 4 is arranged around the post portion 331, that is, the post portion 331 can also be provided to play the role of limiting the conductive spring 4, thereby improving the stability and reliability of electrical conduction between the conductive spring 4 and the conductive member 31. It should be noted that the conductive spring 4 described herein is a cylindrical spring.

Further, as shown in FIG. 3, the insulating bracket 33 may further include an outer cover portion 333, the post portion 331 being arranged inside the outer cover portion 333 and connected to the outer cover portion 333, and the outer cover portion 333 being connected to the insulating member 32, so as to define an accommodating cavity between the insulating bracket 33 and the insulating member 32, and the conductive member 31 being arranged inside the accommodating cavity. In this way, the accommodating cavity jointly defined by the insulating member 32 and the insulating bracket 33 can be used to easily and effectively fix the conductive member 31, and can also protect the conductive member 31 from contact with the outside, so as to avoid the contact of the conductive member 31 with other conductive media, which otherwise affects the accuracy of detection, thereby improving the reliability of determination.

Optionally, as shown in FIG. 3, the insulating member 32 further includes a connecting periphery 322, the connecting periphery 322 being connected to an edge of a touch panel and folded over toward a side of the first conductive portion 311 away from the touch surface portion 321, so as to be connected to an end of the outer cover portion 333 close to an insulating surface portion, thereby connecting the insulating member 32 to the insulating bracket 33.

Optionally, the shape of the conductive member 31 matches with the shape of the accommodating cavity, so that the accommodating cavity jointly defined by the insulating member 32 and the insulating bracket 33 can be used, as shown in FIG. 3, to reliably fix the conductive member 31 and improve the structural compactness.

Optionally, as shown in FIG. 3, the outer cover portion 333 can cover the conductive spring 4, in this way, the outer cover portion 333 can protect the conductive spring 4 from contact with the outside as much as possible, and avoid the contact of the conductive spring 4 with other conductive media, which otherwise affects the accuracy of detection, so that the reliability of determination can be improved.

Optionally, the shape of the outer cover portion 333 matches with the shape of the conductive spring 4, so that the structural compactness can be improved, and the interference of the outer cover portion 333 on the deformation of the conductive spring 4 can also be avoided, thereby improving the using feel of the button unit 100.

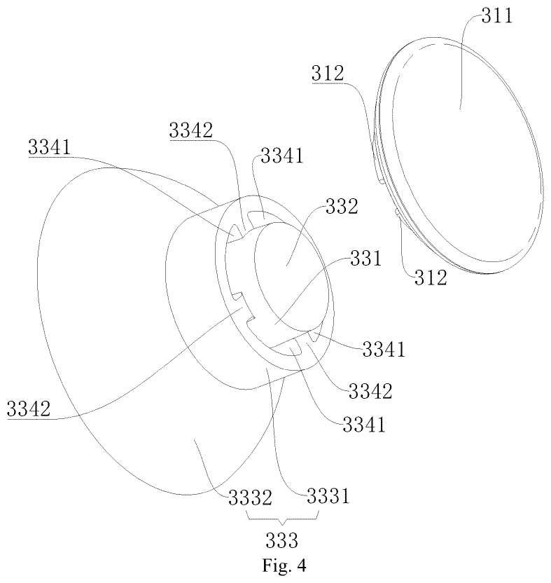

In some embodiments, as shown in FIGS. 3 and 4, the insulating bracket 33 may further include a connecting portion 334, the connecting portion 334 being connected between the post portion 331 and the outer cover portion 333, for example, the connecting portion 334 being connected between an outer wall of the post portion 331 and an inner wall of the outer cover portion 333. The conductive spring 4 and the conductive member 31 are respectively located on two sides of the connecting portion 334 in the axial direction of the post portion 331, avoidance holes 3341 are formed in the connecting portion 334, and the conductive member 31 further includes a second conductive portion 312, the second conductive portion 312 being connected to a side of the first conductive portion 311 facing the circuit board 1, and the second conductive portion 312 passing through the avoidance holes 3341 and being in electrical conduction with the conductive spring 4.

In this way, the connection between the outer cover portion 333 and the post portion 331 can be realized easily and effectively, and the electrical conduction between the conductive member 31 and the conductive spring 4 is ensured, thereby facilitating the machining and design. Moreover, by providing the connecting portion 334 to connect the outer cover portion 333 and the post portion 331, the stability of the outer cover portion 333 and the stability of the post portion 331 can be both improved, and the overall stability of the insulating bracket 33 can be improved, thereby increasing the supporting performance of the insulating bracket 33 and the protection of the insulating bracket to the conductive member 31 and the conductive spring 4. Of course, the present application is not limited to this, and the post portion 331 or the outer cover portion 333 can be designed in a more complicated structural form, so as to realize the connection between the post portion and the outer cover portion, which will not be described in detail here.

Optionally, as shown in FIGS. 3 and 4, the connecting portion 334 includes a plurality of sub-portions 3342, the plurality of sub-portions 3342 are arranged at a distance from each other in a circumferential direction of the post portion 331, each avoidance hole 3341 is formed between every two adjacent sub-portions 3342, and the second conductive portion 312 passes through at least two of the avoidance holes 3341. It should be noted that at least two avoidance holes 3341 are provided. When only two avoidance holes 3341 are provided, the second conductive portion 312 is arranged in each avoidance hole 3341. When more than two avoidance holes 3341 are provided, the second conductive portion 312 is arranged in each of two or more avoidance holes 3341. In this way, the stability and reliability of electrical conduction can be improved. Optionally, second conductive portions 312 are respectively arranged in the avoidance holes 3341, that is, the number of the avoidance holes 3341 is the same as the number of the second conductive portions 312, and a plurality of second conductive portions 312 fit with a plurality of avoidance holes 3341 in a one-to-one correspondence. In this way, the stability and reliability of electrical conduction can be better improved.

Optionally, the shape of the avoidance holes 3341 matches with the shape of the second conductive portions 312, so that the circumferential rotation of the conductive member 31 relative to the post portion 331 is restricted by the connecting portion 334. In this way, the working stability of the conductive member 31 can be improved, and problems such as poor electrical conduction between the second conductive portion 312 and the conductive spring 4 caused by the rotation of the conductive member 31 can be solved, thereby improving the stability of detection.

Optionally, in the circumferential direction of the post portion 331, an arc length of any second conductive portion 312 is greater than that of each sub-portion 3342, so that the stress on the second conductive portion 312 can be reduced, thereby improving the structural reliability of the second conductive portion 312, and further improving the stability and reliability of electrical conduction between the conductive member 31 and the conductive spring 4.

Optionally, the sub-portions 3342 all have the same shape and size and are distributed at a distance from each other in the circumferential direction of the post portion 331, so as to allow all the second conductive portions 312 to have the same shape and size, so that the design and machining can be simplified, and the assembly is facilitated without special alignment. In addition, it should be noted that the post portion 331 is not limited to be cylindrical, for example, the cross section of the post portion may be polygonal, elliptical, even irregular, or the like, which will not be described in detail here.

In some embodiments of the present application, taking a cross section of the post portion 331 as a projection plane, an orthographic projection of the support end 332 is within a range of an orthographic projection of the first conductive portion 311. That is, the area of the support end 332 is smaller than that of the first conductive portion 311, and the coverage of the first conductive portion 311 is larger than that of the support end 332. In this way, the support end 332 can provide a good and reliable supporting effect for the first conductive portion 311, and a conductive surface portion has a larger size, so that the yield of contact between the conductive surface portion and the touch surface portion 321 of the insulating member 32 can be improved, thereby increasing the accuracy of determination. An orthographic projection of an axial end of the conductive spring 4 facing the first conductive portion 311 can be located within the range of the orthographic projection of the first conductive portion 311, so that the conductive spring 4 only needs to be a general cylindrical spring without special design and machining.

Optionally, as shown in FIG. 3, a recess 323 is formed in a side surface of the touch surface portion 321 away from the first conductive portion 311, which can provide an anti-slip effect, so that the user can touch the touch surface portion 321 of the insulating member 32 more stably. Further, taking a cross section of the post portion 331 as a projection plane, in the projection plane, an orthographic projection of the support end 332 is within a range of an orthographic projection of the recess 323, and the orthographic projection of the recess 323 is within the range of the orthographic projection of the first conductive portion 311.

That is, the area of the support end 332 is smaller than that of the recess 323, and the coverage of the recess 323 is larger than that of the support end 332. In addition, the area of the recess 323 is smaller than that of the first conductive portion 311, and the coverage of the first conductive portion 311 is larger than that of the recess 323. In this way, the moderate size of the recess 323 can allow the support end 332 to provide an effective supporting effect while ensuring a larger size of the conductive surface portion, so that the yield of contact between the conductive surface portion and the touch surface portion 321 of the insulating member 32 can be improved, thereby increasing the accuracy of determination.

In some embodiments of the present application, as shown in FIG. 3, the post portion 331 can be a hollow post, and the other axial end of the post portion 331 away from the support end 332 is open. In this way, it is possible to save on the material of the post portion 331, facilitate the machining of the post portion 331, improve the flexibility of the button assembly 3 being touched and pressed, and improve the operating feel.

In addition, when the conductive member 31 includes a plurality of second conductive portions 312, and the plurality of second conductive portions 312 are respectively arranged in a plurality of avoidance holes 3341, the plurality of second conductive portions 312 are arranged around the post portion 331, and an end of the post portion 331 facing the first conductive portion 311 can be arranged in a form in which the cross section is tapered in a direction toward the first conductive portion 311, so that a guiding effect can be provided, thereby facilitating the assembly between the post portion 331 and the conductive member 31.

In addition, when the conductive spring 4 is arranged around the post portion 331, an end of the post portion 331 away from the first conductive portion 311 can be arranged in a form in which the cross section is tapered in a direction away from the first conductive portion 311, so that a guiding effect can be provided, thereby facilitating the assembly between the post portion 331 and the conductive spring 4.

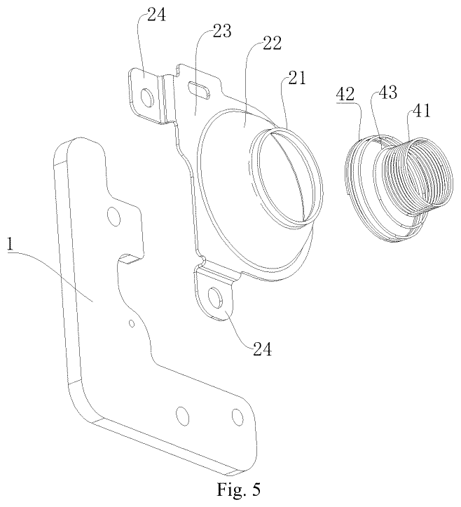

In some embodiments of the present application, as shown in FIGS. 3 and 5, the conductive bracket 2 may include a sleeve portion 21, and the conductive spring 4 is arranged around the sleeve portion 21. In this way, the sleeve portion 21 can be used to limit and support the conductive spring 4, thereby reducing the difficulty in fitting of the conductive bracket 2 with the conductive spring 4, improving the efficiency of assembly between the conductive bracket 2 and the conductive spring 4, and reducing the actual difficulty and machining difficulty of the conductive spring 4.

Further, as shown in FIGS. 3 and 5, the conductive bracket 2 further includes a flared portion 22 coaxially arranged with the sleeve portion 21, wherein the flared portion 22 has an axial end close to the circuit board 1 and the other axial end away from the circuit board 1. For example, an axial direction of the flared portion 22 is arranged perpendicular or substantially perpendicular to the circuit board 1. The flared portion 22 has a cross section that tapers in a direction away from the circuit board 1, the sleeve portion 21 is connected to an end of the flared portion 22 away from the circuit board 1, and an axial end of the conductive spring 4 close to the circuit board 1 abuts against an outer peripheral surface of the flared portion 22. That is, the sleeve portion 21 is located on a side of the flared portion 22 away from the circuit board 1, and an axial end of the sleeve portion 21 close to the flared portion 22 is connected to an axial end of the flared portion 22 close to the sleeve portion 21.

In this way, by allowing an end of the conductive spring 4 away from the conductive member 31 to abut against the outer peripheral surface of the flared portion 22, axial limiting and supporting effects for the conductive spring 4 can be easily and effectively provided, thereby reducing the assembly difficulty, and simplifying the structure and machining. Moreover, the stability of contact between the conductive bracket 2 and the conductive spring 4 is good, so that the reliability of electrical conduction between the conductive bracket 2 and the conductive spring 4 can be improved. In addition, the conductive bracket 2 in this structural form has a good structural stability, so that the reliability and stability of supporting of the conductive bracket 2 to the conductive spring 4 can be increased, thereby improving the feel.

Optionally, as shown in FIGS. 3 and 5, the conductive bracket 2 further includes an end plate portion 23 and a foot portion 24, the end plate portion 23 is connected to an outer periphery of an end of the flared portion 22 close to the circuit board 1, and the foot portion 24 extends from an edge of the end plate portion 23 in a direction toward the circuit board 1 and is supported on the circuit board 1, so as to allow the end plate portion 23 to be in clearance-fit with the circuit board 1. In this way, the foot portion 24 can be used to achieve a fixed connection with the circuit board 1, the foot portion 24 can also be used to achieve an electrical conduction with the circuit board 1, and additionally, the foot portion 24 can be used to achieve a contact support with the circuit board 1, so that the contact and force applied by the conductive bracket 2 on the circuit board 1 is reduced, thereby providing an effect of protecting the circuit board 1.

For example, optionally, the foot portion 24 can be fixedly connected to the circuit board 1 by means of screwing or welding, so that the electrical conduction can also be realized, thereby simplifying the machining and assembly.

The conductive spring 4 described herein may be a spiral spring, so that the spring can be arranged around and matches with the post portion 331 and the conductive bracket 2. In some optional embodiments, as shown in FIGS. 3 and 5, when the conductive spring 4 is a spiral spring, and the conductive spring 4 has an axial end close to the circuit board 1 and the other axial end away from the circuit board 1, the conductive spring 4 may include a first spring section 41, a second spring section 42, and a third spring section 43 that are connected in an axial direction of the conductive spring 4, the second spring section 42 is located at a side of the first spring section 41 close to the circuit board 1, the third spring section 43 is connected between the first spring section 41 and the second spring section 42, the second spring section 42 has a larger diameter than the first spring section 41, the second spring section 42 is arranged around the sleeve portion 21, the button assembly 3 includes the post portion 331, and the first spring section 41 is arranged around the post portion 331. In this way, the conductive spring 4 has a strong stability, a good elastic change effect, and is less prone to radial deflection, thereby improving the operating feel. Moreover, the conductive spring 4 in this form is easy to process, and has a low cost without special manufacturing.

In addition, in some optional embodiments, as shown in FIGS. 3-5, when the button assembly 3 includes the outer cover portion 333 that covers the conductive spring 4, the outer cover portion 333 can be configured in a shape that generally matches with the conductive spring 4. For example, the outer cover portion 333 may include a first cover portion 3331 and a second cover portion 3332, wherein the first cover portion 3331 is cylindrical, the second cover portion 3332 is conical, the first cover portion 3331 is coaxially arranged with the second cover portion 3332, the second cover portion 3332 is connected to a side of the first cover portion 3331 close to the circuit board 1, and the second cover portion 3332 has a cross-sectional area that gradually increases in a direction toward the circuit board 1, so that the outer cover portion 333 can provide effective avoiding and protecting effects for the conductive spring 4. Moreover, when the conductive bracket 2 includes the flared portion 22 mentioned above, as the compression of the conductive spring 4, the second cover portion 3332 is always in clearance-fit with the flared portion 22, so that mutual interference between the outer cover portion 333 and the flared portion 22 can be avoided, thereby improving the movement flexibility of the button assembly 3.

In addition, for the fit relationship and connection relationship between the post portion 331 and the outer cover portion 333 in above two paragraphs of the embodiment, reference may be made to but not limited to the description in other paragraphs herein, which will not be described in detail here.

An electronic device according to an embodiment of a second aspect of the present application is described below with reference to the accompanying drawings.

Specifically, the electronic device may include a device body and a button unit 100, the button unit 100 being arranged on the device body and being a button unit 100 according to the embodiment of the first aspect of the present application. In this way, the overall touch performance of the electronic device can be improved.

It should be noted that the specific type of the device body is not limited, for example, the device body may be an AR device or a VR device, which may include a headpiece portion and a handle portion, and the button unit 100 may be arranged on the headpiece portion or the handle portion at a desired position, so that the overall touch experience of the electronic device can be improved. Where a user cannot see the device body itself due to wearing a headpiece, the user can perceive the effect of pressing the button unit 100 through an elastic feedback of the conductive spring 4, thereby improving the user experience.

In addition, after the specific type of the electronic device according to the embodiment of the present application is determined, other configurations and operations of the device body are known to those of ordinary skill in the art, and will not be described in detail here.

A button unit 100 according to a specific embodiment of the present application is described below.

The button unit 100 includes: a circuit board 1, a conductive bracket 2, a button assembly 3, and a conductive spring 4, wherein the button assembly 3 includes: a conductive member 31, an insulating member 32, and an insulating bracket 33.

The circuit board 1 may be a PCBA as a carrier of electronic components.

The insulating member 32 includes a touch surface portion 321, which is a portion of the button unit 100 for contacting with and being pressed by a user's finger. The insulating member 32 may be made of a silicone material or the like, which not only has a good insulating performance, but also can provide a good touching feel, and is less prone to damage caused by bumping and has a long service life. Of course, the present application is not limited to this, and the insulating member 32 may also be made of a rubber material, a glass material, etc., which will not be described in detail here.

The conductive member 31, the conductive spring 4, and the conductive bracket 2 are all made of metal materials as components of a path for charges, realizing a good structural reliability and a long service life. Of course, the present application is not limited to this, and the conductive member 31, the conductive spring 4, and the conductive bracket 2 may also be made of other conductive materials, such as conductive plastic and conductive rubber.

As a base body of the button assembly 3 for mounting and supporting the conductive member 31, the insulating member 32, etc., the insulating bracket 33 may be made of a plastic material, thereby achieving good insulating, supporting and protecting performances, and also realizing a low cost, a light weight, and a high reliability. Of course, the present application is not limited to this, and the insulating bracket 33 may also be made of a plastic material, a wood material, etc.

In this way, since all components are made of common materials, and have simple structural shapes, special materials and special designs are not needed, thereby reducing the cost.

In order to achieve the touch function of the button unit 100, the conductive member 31 is assembled or embedded inside the insulating member 32 and the insulating bracket 33, and is in electrical conduction with the circuit board 1 via the conductive spring 4 and the conductive bracket 2, so that the path for charges is realized, which makes it possible to sense a change of charges of the touch surface portion 321 of the insulating member 32, and then, by means of software detection, whether the user touches a surface of the touch surface portion 321 is determined, thereby achieving the touch function of the button unit 100.

The machining method of the button unit 100 in this embodiment is not limited. For example, various components can be correspondingly processed by means of suitable machining methods, such as injection molding, metal machining, sheet metal machining, spring making, and PCBA making. During assembly, the conductive spring 4 and the conductive bracket 2 can be combined into a whole, and then the whole can be fixed on the circuit board 1 to form a first semi-finished product. The conductive member 31 can be combined with the insulating bracket 33 by means of assembly or insert injection molding, or the like, to form a second semi-finished product, and then the insulating member 32 is combined with the second semi-finished product by means of sleeving, double-shot injection molding or insert injection molding, or the like, to form a complete button assembly 3. After that, the button assembly 3 is combined with the first semi-finished product, thereby completing the assembly of the button unit 100.

In the description of the present application, it should be understood that orientation or position relationships indicated by terms such as “axial”, “radial”, and “circumferential” are based on orientation or position relationships shown in the accompanying drawings and are merely for ease of description of the present application and simplification of the description, rather than indicating or implying that the components or elements referred to must have a specific orientation or be constructed and operated in a specific orientation, and therefore cannot be construed as limiting the present application.

In addition, the terms “first” and “second” are used for descriptive purposes only, and cannot be construed as indicating or implying relative importance or implicitly indicating the number of technical features indicated. Thus, the features defined with “first” and “second” may explicitly or implicitly include one or more features. In the description of the present application, the meaning of “a plurality of” is two or more, unless explicitly and specifically defined otherwise.

In the present application, unless explicitly stated or limited otherwise, the terms such as “mounting”, “connecting”, “connection” and “fixing” should be interpreted broadly, for example, it may be a fixed connection, a detachable connection or an integrated connection; may be a mechanical connection, an electrical connection, or a communication connection; or may be a direct connection or an indirect connection by means of an intermediate medium, or may be communication between interiors of two elements or interaction between the two elements. For those of ordinary skill in the art, the specific meaning of the terms mentioned above in the present application should be construed according to specific circumstances.

In the present application, unless otherwise explicitly specified and defined, a first feature being “on” or “under” a second feature may be the first feature being in direct contact with the second feature, or the first feature being in indirect contact with the second feature via an intermediate medium. Furthermore, the first feature being “over”, “above” and “on top of” the second feature may be the first feature being directly above or obliquely above the second feature, or only means that the level of the first feature is higher than the second feature. The first feature being “underneath”, “below” and “beneath” the second feature may be the first feature being directly below or obliquely below the second feature, or only means that the level of the first feature is less than the second feature.

In the description of this specification, descriptions with reference to the terms such as “an embodiment”, “some embodiments”, “example”, “specific example”, or “some examples” mean that specific features, structures, materials, or characteristics described with reference to the embodiment or example are included in at least one embodiment or example of the present application. In the specification, the schematic expressions of the terms mentioned above are not necessarily directed to the same embodiment or example. Moreover, the specific features, structures, materials or characteristics described can be combined in any one or more embodiments or examples in any suitable manner. In addition, without any contradiction, those skilled in the art may incorporate and combine different embodiments or examples and features of the different embodiments or examples described in this specification.

Although the embodiments of the present application have been shown and described, those of ordinary skill in the art can understand that various changes, modifications, substitutions, and variations can be made to these embodiments without departing from the principles and spirit of the present application. The scope of the present application is defined by the claims and equivalents thereof.

1. A button unit, comprising:
a circuit board, a capacitive sensor being provided on the circuit board;
a conductive bracket fixed on the circuit board and in electrical conduction with the capacitive sensor;
a button assembly movable relative to the conductive bracket and comprising a conductive member and an insulating member, the conductive member comprising a first conductive portion, and the insulating member comprising a touch surface portion covering an outer side of the first conductive portion; and
a conductive spring sandwiched between the conductive bracket and the button assembly and in electrical conduction with each of the conductive bracket and the conductive member.

2. The button unit according to claim 1, wherein the button assembly further comprises
an insulating bracket connected to the insulating member and comprising a post portion, an axial end of the post portion being a support end, and the first conductive portion being sandwiched between the support end and the touch surface portion.

3. The button unit according to claim 2, wherein the conductive spring is arranged around the post portion.

4. The button unit according to claim 2, wherein the insulating bracket further comprises
an outer cover portion, the post portion being arranged inside and connected to the outer cover portion, and the outer cover portion being connected to the insulating member, so as to define an accommodating cavity between the insulating bracket and the insulating member, and the conductive member being arranged inside the accommodating cavity.

5. The button unit according to claim 4, wherein the outer cover portion covers the conductive spring.

6. The button unit according to claim 5, wherein the insulating bracket further comprises
a connecting portion connected between the post portion and the outer cover portion, the conductive spring and the conductive member being respectively located on two sides of the connecting portion in an axial direction of the post portion, avoidance holes being formed in the connecting portion, the conductive member further comprising a second conductive portion connected to a side of the first conductive portion facing the circuit board, and the second conductive portion passing through the avoidance holes and being in electrical conduction with the conductive spring.

7. The button unit according to claim 6, wherein the connecting portion comprises a plurality of sub-portions arranged at a distance from each other in a circumferential direction of the post portion, each avoidance hole is formed between every two adjacent sub-portions, and the second conductive portion passes through at least two of the avoidance holes.

8. The button unit according to claim 7, wherein the shape of the avoidance holes matches with the shape of the second conductive portion, so that the circumferential rotation of the conductive member relative to the post portion is restricted by the connecting portion.

9. The button unit according to claim 2, wherein taking a cross section of the post portion as a projection plane, an orthographic projection of the support end is within a range of an orthographic projection of the first conductive portion, and an orthographic projection of an axial end of the conductive spring facing the first conductive portion is within the range of the orthographic projection of the first conductive portion.

10. The button unit according to claim 9, wherein a recess is formed in a side surface of the touch surface portion away from the first conductive portion, in the projection plane, the orthographic projection of the support end is within a range of an orthographic projection of the recess, and the orthographic projection of the recess is within the range of the orthographic projection of the first conductive portion.

11. The button unit according to claim 2, wherein the post portion is a hollow post, and the other axial end of the post portion away from the support end is open.

12. The button unit according to claim 1, wherein the conductive bracket comprises a sleeve portion, and the conductive spring is arranged around the sleeve portion.

13. The button unit according to claim 12, wherein the conductive bracket further comprises a flared portion coaxially arranged with the sleeve portion and having a cross section that tapers in a direction away from the circuit board, the sleeve portion is connected to an end of the flared portion away from the circuit board, and an axial end of the conductive spring close to the circuit board abuts against an outer peripheral surface of the flared portion.

14. The button unit according to claim 13, wherein the conductive bracket further comprises an end plate portion and a foot portion, the end plate portion is connected to an outer periphery of an end of the flared portion close to the circuit board, and the foot portion extends from an edge of the end plate portion in a direction toward the circuit board and is supported on the circuit board, so as to allow the end plate portion to be in clearance-fit with the circuit board.

15. The button unit according to claim 12, wherein the conductive spring comprises a first spring section, a second spring section, and a third spring section that are connected in an axial direction of the conductive spring, the second spring section is located at a side of the first spring section close to the circuit board, the third spring section is connected between the first spring section and the second spring section, the second spring section has a larger diameter than the first spring section, the second spring section is arranged around the sleeve portion, the button assembly comprises the post portion, and the first spring section is arranged around the post portion.

16. An electronic device, comprising: a device body and a button unit, the button unit being arranged on the device body and being a button unit, and the button unit comprising:
a circuit board, a capacitive sensor being provided on the circuit board;
a conductive bracket fixed on the circuit board and in electrical conduction with the capacitive sensor;
a button assembly movable relative to the conductive bracket and comprising a conductive member and an insulating member, the conductive member comprising a first conductive portion, and the insulating member comprising a touch surface portion covering an outer side of the first conductive portion; and
a conductive spring sandwiched between the conductive bracket and the button assembly and in electrical conduction with each of the conductive bracket and the conductive member.

17. The electronic device according to claim 16, wherein the device body comprises a headpiece portion and a handle portion, and the button unit is arranged on the handle portion.

18. The button unit according to claim 3, wherein the insulating bracket further comprises
an outer cover portion, the post portion being arranged inside and connected to the outer cover portion, and the outer cover portion being connected to the insulating member, so as to define an accommodating cavity between the insulating bracket and the insulating member, and the conductive member being arranged inside the accommodating cavity.

19. The button unit according to claim 3, wherein taking a cross section of the post portion as a projection plane, an orthographic projection of the support end is within a range of an orthographic projection of the first conductive portion, and an orthographic projection of an axial end of the conductive spring facing the first conductive portion is within the range of the orthographic projection of the first conductive portion.

20. The button unit according to claim 3, wherein taking a cross section of the post portion as a projection plane, an orthographic projection of the support end is within a range of an orthographic projection of the first conductive portion, and an orthographic projection of an axial end of the conductive spring facing the first conductive portion is within the range of the orthographic projection of the first conductive portion.
